(19) United States
(12) Patent Application Publication
(10) Pub. No.: US 2004/0152276 A1
(43) Pub. Date: Aug. 5, 2004

(54) Device, and substrate on which circuit and antenna are formed

(76) Inventor: Naoki Nishimura, Tokyo (JP)

Correspondence Address: ROBIN BLECKER & DALEY, 2ND FLOOR, 330 MADISON AVENUE, NEW YORK, NY, 10017, US

(21) Appl. No.: 10/748,807

(22) Filed: Dec. 30, 2003

(30) Foreign Application Priority Data
Jan. 14, 2003 (JP) 2003-006369
Jan. 14, 2003 (JP) 2003-006370

(51) Int. Cl. H01L 21/331

(52) U.S. Cl. 438/365; 438/378

(57) ABSTRACT

A hybrid device is formed by bonding together a substrate on which a micromachine (MEMS) is formed, and a semiconductor layer on which a semiconductor device is formed through an adhesion layer. The semiconductor layer can be formed by, e.g., bonding together the substrate and a member which has a separation layer (e.g., a porous layer) under the semiconductor layer on which the semiconductor device is formed, and then dividing the member at the separation layer. Alternatively, the hybrid device includes a semiconductor layer on which a circuit is formed and an antenna substrate on which an antenna is formed. The semiconductor layer and antenna substrate are bonded together, and the semiconductor layer is formed by separating, at a separation layer, a substrate which includes the separation layer.

### FIELD OF THE INVENTION

The present invention relates to a device having a semiconductor device and micromachine, and a substrate on which a circuit and antenna are formed.

### BACKGROUND OF THE INVENTION

Recently, a sensor or a communication device which uses a micromachine has received attention. The micromachine is called a MEMS (microelectromechanical systems).

An RF (Radio Frequency)-MEMS receives attention as an application of a MEMS technique. RF-MEMS devices include, e.g., a switch, inductor, variable capacitor, and the like. Each device has an advantage over a device which does not use a MEMS. For example, a switch has a smaller insertion loss at a high frequency and has low isolation as compared to, e.g., a general PIN diode. As for an inductor, the winding direction can be set to be parallel to a substrate, and thus a magnetic field to be generated is not applied to an underlying high-frequency circuit. As for a variable capacitor, the electrode width of the capacitor physically changes, and thus a filter with a high Q value can be formed. For example, assume that only a switch is formed by a MEMS technique. In this case, an entire high-frequency circuit can be arranged by constructing the remaining portion not from a MEMS but from a conventional semiconductor circuit, and utilizing the excellent high-frequency characteristics of the formed MEMS switch.

A MEMS, such as an RF-MEMS switch, RF-MEMS inductor, or RF-MEMS variable capacitor has a movable mechanical portion and thus is increasing in size.

Accordingly, if a MEMS and a high-frequency circuit are arranged side by side, the entire size increases.

An RF-MEMS has a film thickness of several ten μm and a width of several μm like, e.g., a combshaped electrode and thus is often manufactured by electrochemically depositing a desired structure in a solution, i.e., a so-called electrodeposition process. In contrast to this, as for a semiconductor portion such as a high-frequency circuit or amplifier circuit, the constituent elements have a submicron order (about 0.1 to 0.5 μm), and a dry process such as sputtering, CVD, or the like is used in the manufacturing process.

Since a MEMS portion and a semiconductor portion such as a high-frequency circuit or amplifier circuit are different from each other in size required, manufacturing equipment, environment such as the cleanliness level required, and the like, they are often manufactured in separate manufacturing lines. Thus, it is difficult to manufacture a MEMS portion and a semiconductor portion on a single substrate in the same manufacturing line.

As described above, a conventional device having a semiconductor device and micromachine has the following problems. 1) Since a portion formed by a MEMS technique has a movable mechanical portion and requires a relatively large area, the size of the entire device increases when the portion is arranged parallel to a semiconductor circuit. 2) A semiconductor portion and MEMS portion are manufactured in different processes. When they are formed on a single substrate, a liquid for use in an electrodeposition process and having high acidity may come into contact with the semiconductor portion. To prevent this, the complexity of the process needs to be increased.

In a conventional technique in which a substrate on which a MEMS is formed and a substrate on which a semiconductor circuit is formed are bonded together with an adhesive or the like, the substrate on which the MEMS is formed is arranged on the semiconductor circuit formed on the substrate of silicon through an insulating film. In this case, the thickness of the entire device formed increases. It is difficult to apply the device to an application which requires flexibility and to stack the device and another member.

An IC-equipped radio tag in the form of, e.g., a card, tag, coin, or the like has abundant information and high security performance, and is becoming widespread in the fields of transportation, distribution, and information communication, and the like. Out of various radio tags, a non-contact radio tag which has no external terminal on its body and performs power supply and transmission/reception of signals by a radio system has recently received attention. This is because it prevents data from destruction by electrostatic electricity entering from a terminal for connection, data errors by poor contact, and incapability of transmission and reception.

Application examples of a non-contact radio tag which uses such a radio system include, e.g., a SUIKA card which allows passage through a ticket gate of a station by holding the card over the ticket gate, a car key which can prevent imitation, and the like. For a non-contact radio tag, e.g., a structure in which a circuit module which includes an IC chip 1701 and antenna coils 1702 for radio communication connected to the pad portions of the IC chip 1701 is fixed by heat seal with a covering material 1703 such as vinyl chloride resin has been proposed, as shown in FIG. 17.

As a radio tag, a wire-wound coil, a conductive paste on an insulating substrate, a pattern of, e.g., a metal film, or the like is generally used. To implement a smaller radio tag, a radio tag in which an antenna coil is formed on an IC chip is also proposed, as disclosed in, e.g., Japanese Patent Laid-Open No. 2001-257292. Each of these radio tags is characterized in that information is read/written from/in the radio tag through a reader by radio communication. If a radio tag is to be mounted on a thin device such as an IC card, it needs to have high bending strength. When the user carries a radio tag, as in the case of an IC card, a bending force may be applied to the radio tag upon storage. To prevent it from breaking when being bent, the radio tag needs to be thinned and be provided with flexibility.

Japanese Patent Laid-Open No. 2002-231909 discloses a technique which uses a bonded substrate stack to form a semiconductor chip having a thinned semiconductor layer. As a semiconductor device is miniaturized and highly integrated, and the chip heat density increases significantly, an LSI chip to be mounted on a thin device is required to be thinned in terms of heat dissipation and mechanical flexibility. Thus, this technique is effective.

The above-mentioned radio tag disclosed in Japanese Patent Laid-Open No. 2001-257292 is formed on an Si substrate, and thus it is difficult to thin a semiconductor layer. A process of forming an antenna coil for use in a radio tag is an electrodeposition process which performs processing in a relative larger scale of several μm or more and exposes a substrate to an acidic solution while a process of forming a radio communication circuit is a semiconductor process which performs processing in a relatively smaller scale of submicron or less and mainly uses a vacuum technique such as sputtering or dry etching. For this reason, use of these different processes in a mixed manner on a single substrate poses a problem such as an increase in process complexity. Particularly if an antenna coil is to be formed on a substrate on which a semiconductor circuit is formed, as disclosed in Japanese Patent Laid-Open No. 2002-083894, the underlying semiconductor circuit may be damaged during an electrodeposition process.

The method disclosed in Japanese Patent Laid-Open No. 2002-231909 can thin the semiconductor circuit portion of an IC chip. However, the method poses a problem when an antenna coil for use in a radio tag and a radio communication circuit are formed on a single substrate, as described above.

### SUMMARY OF THE INVENTION

The present invention has been made on the basis of recognition of the above-mentioned problems, and has as its object to provide, e.g., a thin device having a semiconductor device and micromachine, and a thin substrate on which a circuit and antenna are formed.

According to the first aspect of the present invention, there is provided a device which has a semiconductor device and a micromachine, comprising a semiconductor layer on which the semiconductor device is formed, and a substrate on which the micromachine is formed, wherein the semiconductor layer and substrate are stacked, and the semiconductor layer is obtained by separating, at a separation layer, a member which has the separation layer under the semiconductor layer.

According to the second aspect of the present invention, there is provided a device which has a semiconductor device and a micromachine, comprising a semiconductor layer on which the semiconductor device is formed, and a substrate on which the micromachine is formed, wherein the semiconductor layer has a first surface and a second surface, the first surface is bonded to the substrate directly or through a bonding layer, and the second surface adjoins a layer whose structure is more fragile than the semiconductor layer.

According to the third aspect of the present invention, there is provided a device which has a semiconductor device and a micromachine, comprising a semiconductor layer on which the semiconductor device is formed, and a substrate on which the micromachine is formed, wherein the semiconductor layer and substrate are stacked, and the semiconductor layer is formed by epitaxial growth.

According to the forth aspect of the present invention, there is provided a device which has a semiconductor device and a micromachine, comprising a semiconductor layer on which the semiconductor device is formed, and a substrate on which the micromachine is formed, wherein the semiconductor layer and substrate are stacked, and the semiconductor layer has a thickness of not more than 50 μm.

According to the fifth aspect of the present invention, there is provided a device which has a semiconductor device and a micromachine, comprising a semiconductor layer on which the semiconductor device is formed, and a substrate on which the micromachine is formed, wherein the semiconductor layer and substrate are stacked, and the semiconductor layer has a thickness of not more than 30 μm.

According to the sixth aspect of the present invention, there is provided a substrate comprising a semiconductor layer on which a circuit is formed, and an antenna substrate on which antennas are formed, wherein the semiconductor layer and antenna substrate are bonded together, and the semiconductor layer is formed by separating, at a separation layer, a substrate which includes the separation layer.

According to the seventh aspect of the present invention, there is provided a method of manufacturing a device which has a semiconductor device and a micromachine, comprising a step of preparing a member which has a semiconductor layer and a separation layer and in which the semiconductor layer is arranged on the separation layer, a step of preparing a substrate on which the micromachine is formed, and a step of bonding a side of the member having the semiconductor layer to the substrate directly or through a bonding layer to manufacture a bonded substrate stack.

According to the eighth aspect of the present invention, there is provided the above mentioned method, wherein the step of preparing the substrate further comprises a step of preparing an antenna substrate on which an antenna is formed, and the step of manufacturing the bonded substrate stack further comprises a step of bonding the side of the member having the semiconductor layer to the antenna substrate directly or through a bonding layer to manufacture a bonded substrate stack.

According to the ninth aspect of the present invention, there is provided a method of manufacturing a substrate, comprising a step of preparing a member which has a semiconductor layer and a separation layer and in which the semiconductor layer is arranged on the separation layer, a step of preparing an antenna substrate on which an antenna is formed, and a step of bonding a side of the member having the semiconductor layer to the antenna substrate directly or through a bonding layer to manufacture a bonded substrate stack.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a view showing an example of the sectional structure of a device which hybridizes a semiconductor device and micromachine according to a preferred embodiment of the present invention;

FIG. 2 is a plan view of the hybrid device shown in FIG. 1, as seen from above;

FIGS. 3A to 3F are views showing an example of a method of manufacturing a MEMS element;

FIGS. 4A and 4B are views showing the OFF and ON states of a MEMS switch 1 shown in FIG. 1;

FIGS. 5A to 5H are views showing an example of a process of manufacturing a device which hybridizes a semiconductor device and micromachine according to the preferred embodiment of the present invention;

FIG. 6 is a block diagram showing an example of a radio communication device;

FIG. 7 is a view showing a radio communication device as an application of a hybrid device of the present invention;

FIGS. 8A to 8C are views illustrating a method of electrically connecting a substrate on which a micromachine is formed and a semiconductor layer on which a semiconductor device or semiconductor circuit is formed;

FIG. 9 is a view showing an example of the sectional structure of substrates according to a preferred embodiment of the present invention;

FIG. 10 is an exemplary plan view of the substrate according to the present invention;

FIG. 11 is a view showing an application example which utilizes the features of a substrate according to the preferred embodiment of the present invention;

FIG. 12 is a view showing an application example which utilizes the features of a substrate according to the preferred embodiment of the present invention;

FIG. 13 is a sectional view showing a case wherein a substrate according to the preferred embodiment of the present invention is mounted on a laminated plastic;

FIG. 14 is a sectional view showing a case wherein a substrate according to the preferred embodiment of the present invention is mounted on a laminated plastic;

FIGS. 15A to 15K are views showing an example of a process for substrates according to the preferred embodiment of the present invention;

FIGS. 16A to 16F are views showing an example of a process for a substrate according to the preferred embodiment of the present invention; and

FIG. 17 is a view showing the sectional structure of a conventional radio tag.

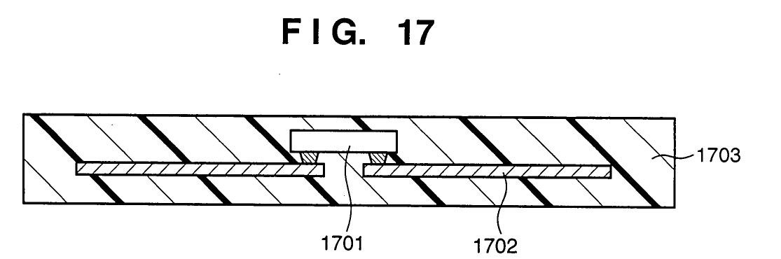

### DETAILED DESCRIPTION OF THE PREFERRED EMBODIMENTS

Preferred embodiments of the present invention will be described below with reference to the accompanying drawings.

In an explanation of a preferred embodiment of the present invention, the structure of a device (to be referred to as a hybrid device hereinafter) having a semiconductor device (or semiconductor circuit) and a MEMS (micromachine) will be described first.

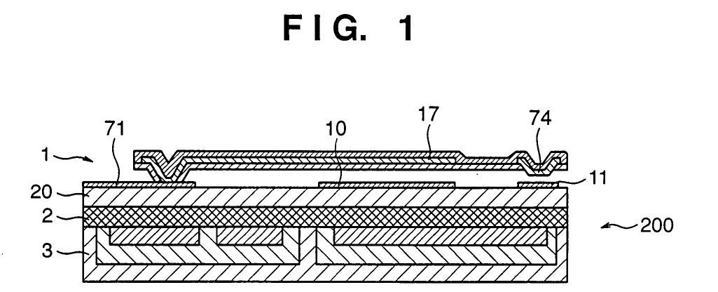

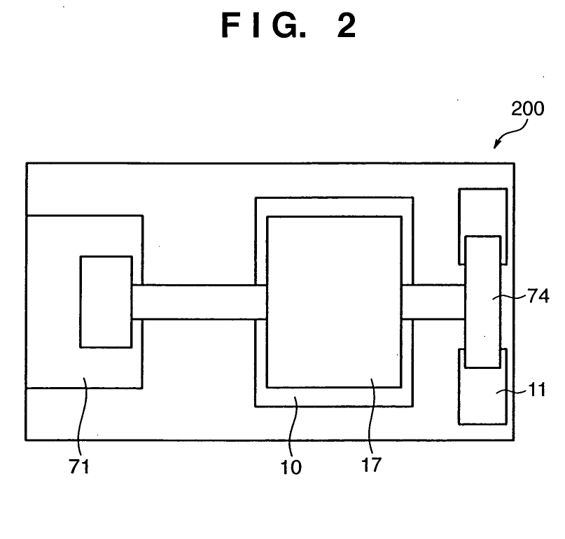

FIG. 1 is a view showing an example of the sectional structure of a hybrid device according to the preferred embodiment of the present invention. FIG. 1 shows a hybrid device which has a MEMS switch as a MEMS element and a radio communication function. A hybrid device 200 shown in FIG. 1 is formed by stacking a substrate 20 on which a MEMS element 1 is formed and a thinned semiconductor layer 3 including a radio communication circuit as a semiconductor circuit through an adhesive or an adhesion layer 2 as a bonding layer. Note that a bonding layer is not necessarily required, and the substrate 20 and semiconductor layer 3 may directly be bonded. FIG. 2 is a plan view of the hybrid device 200 in FIG. 1, as seen from above.

The semiconductor layer 3 preferably has a thickness of 50 μm or less, more preferably, 30 μm or less, and further more preferably, 20 μm or less. The use of a thinned semiconductor layer as a component makes it possible to manufacture a hybrid device with high resistance to bending.

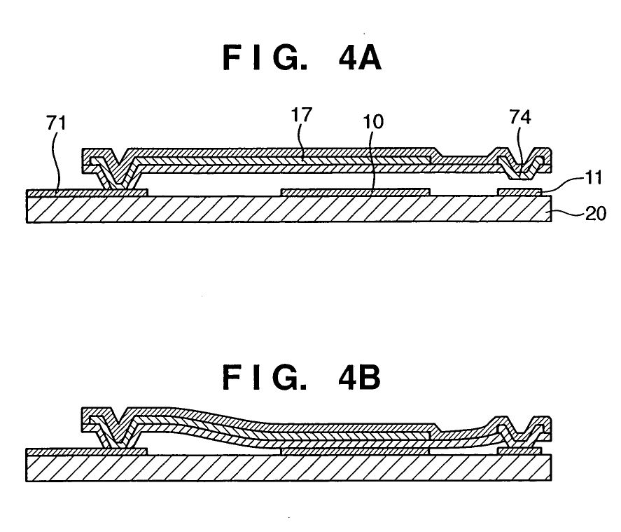

FIGS. 4A and 4B show the OFF and ON states of the MEMS switch 1, respectively. An upper electrode 17 of the switch 1 supported by an anchor portion 71 and a lower electrode 10 formed on the substrate 20 are broad. When a voltage is applied across the electrodes 17 and 10, an electrostatic force causes a terminal 11 and terminal 74 to come into contact with each other.

A MEMS switch physically completely separates two electrodes to leave a space between them in the OFF state while it causes the two electrodes to come into contact with and be electrically connected to each other in the ON state. The MEMS switch has a smaller insertion loss (a transmission loss such as a power loss or voltage loss) and obtains more isolation effect than a semiconductor switching element such as a PIN diode or MESFET. That is, the MEMS switch is characterized in that it can reduce an insertion loss and improve the insulation properties in the OFF state.

A MEMS inductor will also be described. The MEMS inductor, e.g., has a smaller parasitic capacity and can obtain a higher Q value than a normal on-chip planar inductor.

In addition, a MEMS capacitor will be described. As for a variable capacitor which uses a combshaped electrode, the capacity can directly be changed by applying a voltage to reduce the electrode width. Thus, the use of a filter which has a MEMS capacitor as a component can implement a tuning circuit having a high Q value.

Assume that a MEMS switch is inserted among a plurality of dipole antennas and patch antennas. In this case, a high-frequency circuit which supports a plurality of frequencies can be formed by changing the lengths of the antennas. Alternatively, the directivity can be changed by changing the feed pattern of the patch antennas to change the radiation pattern of electromagnetic waves.

As described above, a MEMS element has a wide range of applications in addition to a switch. MEMS elements can include various types of elements (having various functions) as described above.

The hybrid device according to the preferred embodiment of the present invention is formed by stacking not a semiconductor substrate but the semiconductor layer on the substrate 20, on which the MEMS (micromachine) is formed. In the prior art, a substrate on which a MEMS is formed and a semiconductor substrate on which a semiconductor circuit is formed are bonded together with an adhesive, thereby forming a hybrid device. For this reason, the thickness of the entire hybrid device is equal to that of two substrates. On the other hand, the hybrid device according to the preferred embodiment of the present invention, the semiconductor layer is stacked on the substrate on which the MEMS is formed. This can reduce the thickness of the entire hybrid device.

As a method of forming a semiconductor layer, there is available a method of thinning, by grinding or polishing, a substrate on which a semiconductor circuit is formed. Methods of polishing and thinning a substrate include CMP (chemical mechanical polishing). However, a method which uses CMP may increase the complexity of processes or may adversely affect the performance of a MEMS element in polishing. Also, there is a limit to thinning by CMP. In consideration of the possibility of variations in film thickness within a wafer surface, it is difficult to thin a substrate to 50 μm or less.

Assume that an insulating film is formed on a substrate on which a semiconductor circuit is formed, and a MEMS element is formed on the insulating film. In this case, a solution used to form the MEMS element may come into contact with the semiconductor circuit portion. This requires the insulating film to have a sufficiently large thickness and may contaminate a semiconductor device manufacturing environment which should be kept clean at high purity. A manufacturing method according to the preferred embodiment of the present invention can solve the above-mentioned problem.

The substrate 20 on which the MEMS 1 and the thinned semiconductor layer 3 including a semiconductor circuit such as a radio communication circuit are electrically connected to each other. An electrical connection method which uses a conductive metal as an adhesive may be used to connect them.

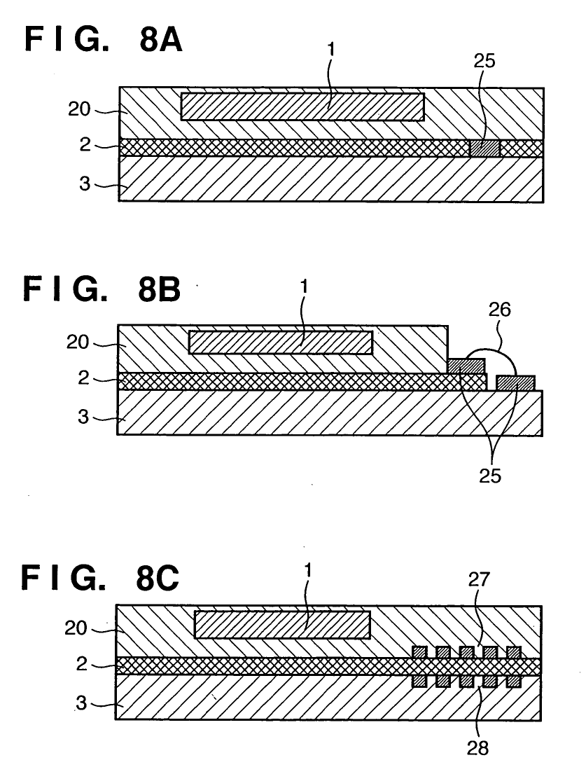

To electrically connect the substrate 20 and semiconductor layer 3, various methods may be used instead, as illustrated in FIGS. 8A to 8C. FIG. 8A shows a method of providing a conductive metal 25 in the adhesive 2. FIG. 8B shows a method of providing pads 25 on the substrate 20 and semiconductor layer 3, respectively, to connect both the pads by wire bonding. FIG. 8C shows a method of electromagnetically connecting (inductively coupling) an electrode on the side of the substrate 20 and an electrode on the side of the semiconductor layer 3 by, e.g., providing coils 27 and 28 on the substrate 20 and semiconductor layer 3, respectively, instead of causing the electrode on the substrate 20 and that on the semiconductor layer 3 to physically come into contact with each other. In the three examples shown in FIGS. 8A to 8C, a nonconductive substance can be employed as the adhesive 2.

Although not shown, the substrate 20 and semiconductor layer 3 may be connected using a packaging method by BGA (Ball Grid Array). Note that the MEMS element 1 is not limited to a switch and may be an RF-MEMS such as an inductor or variable capacitor. Also, the MEMS element 1 may be a sensor such as an acceleration sensor or pressure sensor, or another element.

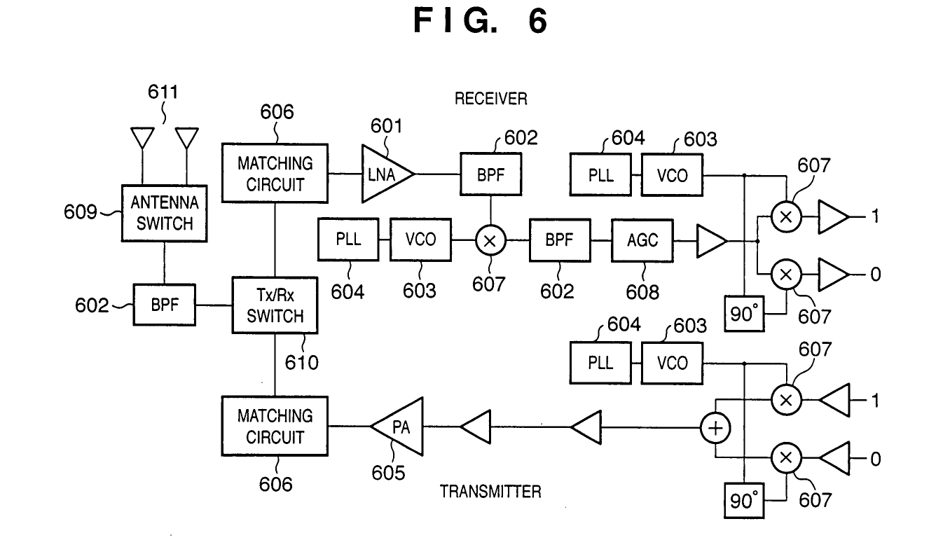

FIG. 6 is a block diagram of a radio communication device which includes a receiver (Rx) and transmitter (Tx). The radio communication device can comprise, e.g., an LNA (low-noise amplifier) 601, BPFs (bandpass filters) 602, VCOs (voltage-controlled oscillators) 603, PLLs (phase-locked loops) 604, a PA (power amplifier) 605, a matching circuit 606, mixers 607, an AGC (automatic gain control) 608, and an antenna switch 609, a transmit-receive (Tx/Rx) switch 610, and antennas 611.

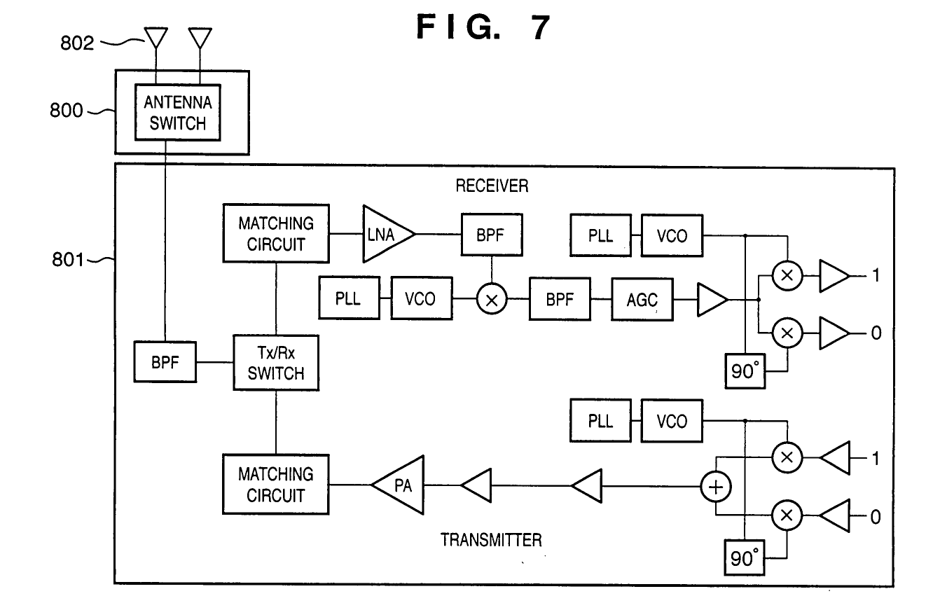

For example, a case will be exemplified wherein the antenna switch 609 is replaced with a MEMS. As shown in FIG. 7, a substrate having a MEMS switch 800 and a semiconductor layer having a semiconductor circuit 801 for radio communication are separately formed and are bonded together. The MEMS switch 800 and antennas 802 may be formed on a single substrate.

Besides the antenna switch, some or all of the BPFs, matching circuit, Tx/Rx switch, LNA, PLLs, VCOs, and mixers can be replaced with MEMSs. MEMSs formed in place of some of the components and the remaining components may be stacked.

In a hybrid device according to the preferred embodiment of the present invention, a semiconductor circuit portion is formed on a thin semiconductor layer. A feature of the hybrid device is that the total thickness is very small. For example, in the above-mentioned example, the total thickness can be set to 25 μm. This structure can be implemented by using a DLT (Device Layer Transfer) process.

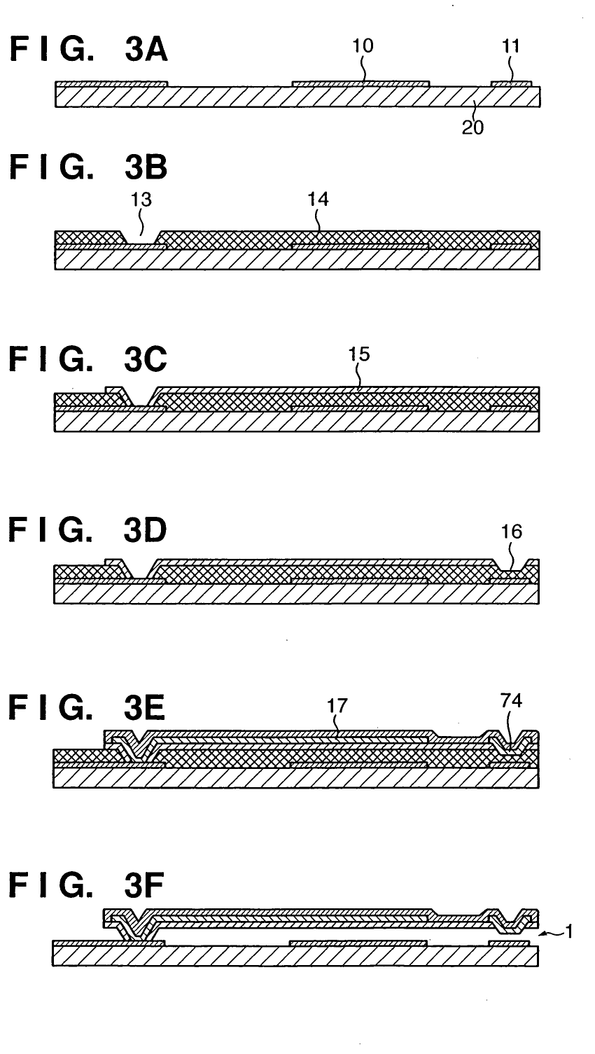

A method of manufacturing a MEMS element will be described with reference to FIGS. 3A to 3F. FIGS. 3A to 3F are views showing an example of a method of manufacturing a MEMS switch.

First, a metal layer comprised of an AuGe film having a thickness of 90 nm, an Ni film having a thickness of 10 nm, and an Au film having a thickness of 1.5 μm is formed on the GaAs substrate 20. The metal layer is patterned to form the lower electrode 10 and terminal 11 (FIG. 3A).

Then, an SiO₂ layer (sacrificial layer) 14 having a film thickness of 2.2 μm is formed, and a portion for a via anchor 13 is subjected to dry etching by CF₄/O₂ plasma (FIG. 3B).

An SiN layer 15 is formed by CVD (FIG. 3C). After the formation of the SiN layer 15, a region of 500 nm in which the contact portion of a switch is to be formed is subjected to etching (FIG. 3D).

A layer comprised of a Ti film having a thickness of 20 nm and an Au film having a thickness of 100 nm is formed. The layer is patterned to form the upper electrode 17 and terminal 74, on which a coating is then provided (FIG. 3E).

Finally, the SiO₂ layer (sacrificial layer) 14 is removed by concentrated hydrofluoric acid (FIG. 3F).

The MEMS switch 1 thus formed has an excellent high-frequency characteristic. By bonding this to a semiconductor layer on which a semiconductor circuit is formed, the hybrid device as shown in FIG. 1 can be manufactured.

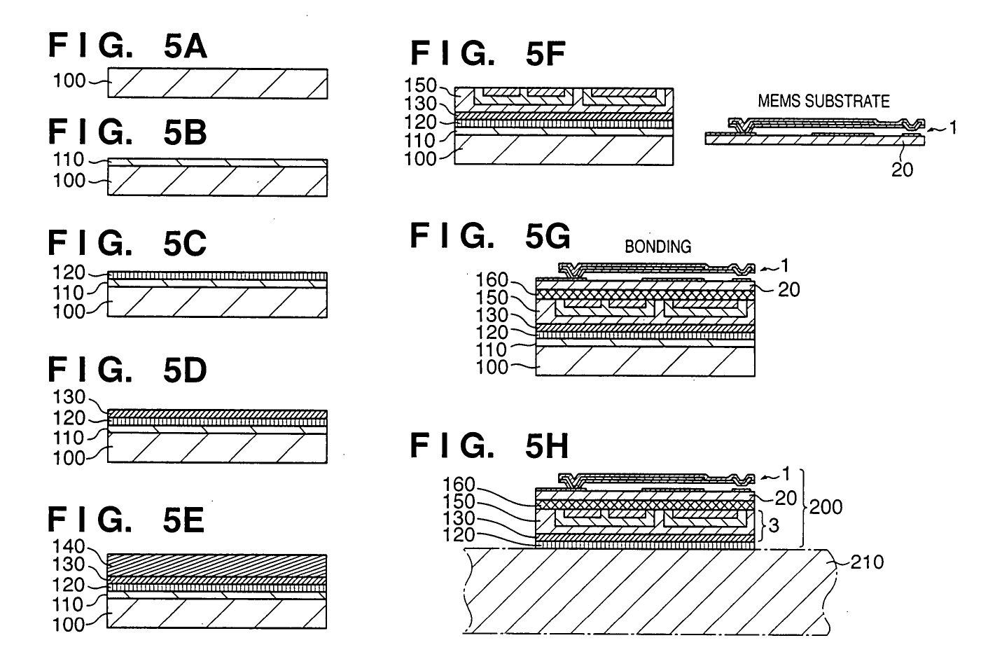

An example of a process of manufacturing a hybrid device which has a semiconductor device and MEMS element will be described with reference to FIGS. 5A to 5H.

FIGS. 5A to 5H are views showing an example of a process of manufacturing a hybrid device according to the preferred embodiment of the present invention. FIGS. 5A to 5H show a DLT (Device Layer Transfer) process. Of these drawings, FIGS. 5A to 5F show a process of manufacturing a substrate which has a separation layer and a semiconductor layer having a semiconductor circuit such as a radio circuit. FIGS. 5G and 5H show a bonding process. An example of a process of manufacturing a semiconductor circuit will be described with reference to FIGS. 5A to 5F.

As shown in FIG. 5A, an Si seed substrate 100 is first prepared as a semiconductor substrate. As shown in FIG. 5B, a first porous Si layer 110 is then formed by the first anodizing step. As shown in FIG. 5C, a second porous Si layer 120 is formed by the second anodizing step. Typically, the first porous Si layer 110 is used as a separation layer, and the second porous Si layer 120 is used to form a good-quality non-porous semiconductor layer thereon. However, both of the first porous Si layer 110 and second porous Si layer 120 or only the second porous Si layer 120 can also be used as a separation layer.

As shown in FIG. 5D, a semiconductor layer (to be described as an Si layer) 130 is formed by hydrogen annealing and high-temperature CVD. As shown in FIG. 5E, a semiconductor layer (to be described as an epitaxial Si layer) 140 is formed by epitaxially growing Si. As shown in FIG. 5F, a semiconductor device such as a high-frequency circuit or an amplifier circuit of a sensor, or a semiconductor integrated circuit 150 is formed by a general semiconductor manufacturing process on the epitaxial Si layer 140.

The manufacturing process illustrated in FIGS. 5A to 5H forms a porous layer comprised of two layers with different porosities in the steps shown in FIGS. 5B and 5C. A porous layer having a one-layer structure or a porous layer comprised of three or more layers may be formed instead. To form a porous layer having a two-layer structure, for example, a porous layer with a high porosity may preferably be formed as the first porous layer to form a porous layer with a low porosity thereon. To form a porous layer having a three-layer structure, the first porous layer with a low porosity, the second porous layer with a high porosity, and the third porous layer with a low porosity may preferably be formed in order of decreasing proximity to the substrate. Preferably, a high porosity indicates a range from, e.g., 10% to 90% while a low porosity indicates a range from, e.g., 0% to 70%. Note that the porosity of a porous layer with a high porosity is set to be higher than that of a porous layer with a low porosity. A plurality of porous layers with different porosities can be formed by, e.g., changing the current density in anodization or changing the type or concentration of an anodizing solution.

To form a porous layer by anodization, a protective film formation step in which a protective film such as a nitride film or oxide film is formed on the inner wall of each pore of the porous layer, and an annealing step in an atmosphere containing hydrogen are preferably performed before growing a semiconductor layer on the porous layer. It is also preferable to perform the annealing step after the protective film formation step.

A separation layer (porous layer) may be formed by ion implantation instead of forming the separation layer by anodization. More specifically, a method of forming an ion-implanted layer by implanting ions of hydrogen, nitrogen, or a rare gas such as helium in the Si shield substrate 100 can be adopted instead of the steps shown in FIGS. 5B to 5D or FIGS. 5B to 5E, including the anodizing step shown in FIGS. 5B and 5C.

In ion implantation, a semiconductor device or semiconductor integrated circuit is formed on the surface of a silicon substrate (or epitaxial wafer). A protective film is then formed on the semiconductor device or semiconductor integrated circuit as needed. After that, ions such as hydrogen ions are implanted at a desired depth to form an ion-implanted layer serving as a separation layer. In this manner, a structure as shown in FIG. 5E is obtained. Note that a semiconductor device may be formed on the surface of the silicon substrate after the ion-implanted layer is formed at a predetermined depth from the surface of the silicon substrate. When a large number of ions are implanted, peeling may occur in the process of forming the semiconductor device. For this reason, the process design is so performed as to prevent peeling during the device formation process by reducing the implantation amount (and then performing annealing as needed).

The semiconductor layer is preferably grown by CVD in the step shown in FIG. 5D at a low growth rate of 20 nm/min or less until the semiconductor layer has a predetermined thickness (e.g., 10 nm). As the semiconductor layer 140, a film made of a compound semiconductor such as GaAs, InP, GaN, and the like is preferably used, in addition to a non-porous single-crystal Si film. If the semiconductor layer 140 is made of single-crystal silicon, e.g., SiH₂Cl₂₁ SiHCl₃, SiCl₄ or SiH₄, or HCl gas can be used as a source gas. As a method of forming the semiconductor layer 140, e.g., MBE or sputtering is preferably used, in addition to CVD.

After forming the porous layers 120 and 130, preferably, the substrate is subjected to the first annealing in a hydrogen-containing atmosphere, and then subjected to the second annealing at a temperature higher than the first annealing temperature prior to growing the semiconductor layer 140. The first annealing temperature preferably falls within the range from 800° C. to 1,000° C., and the second annealing temperature, 900° C. to the melting point of the substrate material. This processing seals the pores in the surface of the porous layer. For example, preferably, the first annealing temperature is set to 950° C., and the second annealing temperature, 1100° C.

As the semiconductor device or semiconductor integrated circuit 150, e.g., a device such as a CMOS, bipolar transistor, diode, coil or capacitor, or a semiconductor integrated circuit such as a DRAM, microprocessor, logic IC, or memory can be manufactured. Applications of the device or circuit can include an electronic circuit, oscillation circuit, light-receiving or light-emitting device, optical waveguide, various sensors, and the like.

The process design may be performed such that a trench or LOCOS (local oxidation of silicon) used for element isolation reaches the separation layer, i.e., the porous layer or ion-implanted layer.

Portions between chip regions in which chips are to be formed respectively may be oxidized by LOCOS or be subjected to mesa etching so as to remove a semiconductor film between the chip regions.

A step of bonding the semiconductor circuit substrate shown in FIG. 5F and the substrate 20, on which the MEMS 1 is formed, and subsequent steps will be described.

In the step shown in FIG. 5G, the MEMS substrate 20, on which the antenna coils 802 and antenna switch 800 are formed, is adhered (bonded) to the surface (the surface opposite to the Si seed substrate 100) of the semiconductor circuit substrate through an adhesion layer (bonding layer) 160 to form a bonded substrate stack. As the adhesion layer 160, an epoxy-based adhesive or any other adhesive can be used.

In the step shown in FIG. 5H, the bonded substrate stack is divided into two between the second porous Si layer 120 and the Si layer 130 or at the second porous Si layer 120. More specifically, a pressure is applied to the side of the second porous Si layer 120 as the separation layer or its vicinity by a fluid. To apply a pressure, e.g., a method of externally injecting a liquid or gas to the separation layer or its vicinity or a method of applying a hydrostatic pressure to the separation layer is preferably used. When a liquid is used as a fluid, water, an etchant, alcohol, or the like is preferable. On the other hand, when a gas is used, air, nitrogen gas, argon gas, or the like is preferable. In separation, ultrasonic vibrations may be applied to the bonded substrate stack.

If the porous layer or ion-implanted layer as the separation layer is not exposed at the side surface of the member in division or separation, the porous layer may be exposed prior to division or separation.

A separation apparatus comprising an enclosed space component for enclosing at least part of the periphery of the member to be divided or separated to form an enclosed space and a pressure application mechanism which applies a pressure higher than that of the external space to the enclosed space is useful in dividing or separating the bonded substrate stack under a hydrostatic pressure (under a pressure applied by a substantially stationary fluid).

Assume that the separation layer is formed by implanting ions of hydrogen, nitrogen, a rare gas such as He, or the like. When the bonded substrate stack is subjected to annealing at a temperature of about 400° C. to 600° C., micro air bubbles (microbubbles or microcavities) formed by ion implantation coagulate to form a layer. Under the circumstances, in this case, the bonded substrate stack can be divided or separated by annealing in addition to or in place of applying a pressure by a fluid. Heating by, e.g., a CO₂ laser is also useful.

The hybrid device 200 thus formed shown in FIG. 5H is constructed by stacking the substrate 20 on which the MEMS (micromachine) 1 is formed and the semiconductor layer 3 on which the semiconductor device or semiconductor circuit is formed. In the example shown in FIG. 5H, the substrate 20 and semiconductor layer 3 are bonded together through the adhesive 160 as a bonding layer. The substrate 20 and semiconductor layer 3 may directly be bonded instead. The semiconductor layer 3 has the first surface to be bonded to the substrate 20 on which the MEMS is formed directly or through the bonding layer and the second surface on the opposite side. Typically, part of the porous layer remains on the second surface. The porous layer remaining on the second surface may be removed by, e.g., etching.

The hybrid device 200 shown in FIG. 5H typically has a plurality of chip regions. The plurality of chip regions are divided into separate chips (chip formation). Processing for chip formation can typically be performed from the separation layer side. To form chips, a general dicing apparatus can be used. Besides, etching, laser abrasion, an ultrasonic cutter, a high-pressure jet (e.g., a water jet), or the like can be used. To form chips by etching, an etchant such as HF+H₂O₂, HF+HNO₃, an alkali solution, or the like is preferably used. As a laser, a YAG laser, CO₂ laser, excimer laser, or the like is preferable.

After chip formation, each chip can be connected to another circuit or packaged. Alternatively, each chip may be bonded to a plastic card (insulating card) 210 directly or through a bonding layer (e.g., an adhesive or adhesion layer), as illustrated in FIG. 5H. Each chip may be bonded to the plastic card (insulating card) 210 directly or through a bonding layer (e.g., an adhesive or adhesion layer) after removing the porous layer 120 remaining on the second surface of the semiconductor layer 3. In this case, the semiconductor layer 3 is bonded to an insulator directly or through the bonding layer.

According to the preferred embodiment of the present invention, a member on which a semiconductor device is formed is not a semiconductor substrate but a semiconductor layer. For this reason, a manufactured chip has high resistance to bending and is suitable for being mounted on or being applied to, e.g., a plastic card (IC card).

The thickness of the semiconductor layer 3 is preferably 50 μm or less, more preferably, 30 μm or less, and most preferably, 20 μm or less. The thickness of the hybrid device 200 is 100 μm or less, and more preferably, 50 μm or less.

The present invention can provide a thin device having a semiconductor device and micromachine.

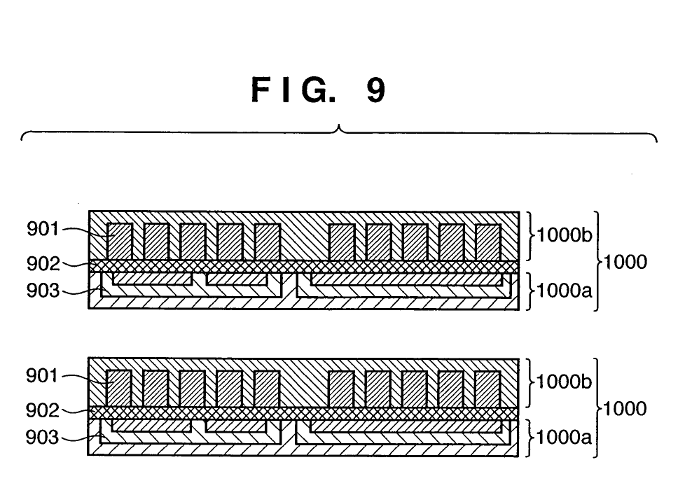

A substrate according to another preferred embodiment of the present invention will be described next. FIG. 9 is a sectional view of devices 1000 as substrates according to another preferred embodiment of the present invention. The device 1000 comprises a semiconductor layer 1000a on which circuits 903 are formed and an antenna substrate 1000b which is bonded to the semiconductor layer 1000a and on which antennas 901 for transmitting/receiving radio waves are formed. The semiconductor layer 1000a includes a portion separated at a separation layer. Although the semiconductor layer 1000a and antenna substrate 1000b are preferably bonded together through an adhesion layer 902, the present invention is not limited to this. For example, the semiconductor layer 1000a and antenna substrate 1000b may be bonded together by causing them to come into contact with each other and then performing annealing, instead of using the bonding layer 902. The device 1000 according to the preferred embodiment of the present invention can be applied to various devices which perform at least one of transmission and reception of radio waves. In the present invention, a case will be exemplified below wherein the device 1000 is applied to a device which performs radio communication.

Referring to FIG. 9, the antennas 901 are formed in the antenna substrate 1000b and are used to at least one of transmission and reception of radio waves. Each antenna 901 can employ an arbitrary material used as a member which performs at least one of transmission and reception of radio waves. For example, a metal material such as copper is desirably used. The thickness of the antenna 901 is not specifically limited, and is, for example, 5 μm.

The bonding layer 902 can employ an arbitrary adhesive as far as it can bond together the semiconductor layer 1000a and antenna substrate 1000b. For example, the bonding layer 902 desirably use a conductive adhesive (e.g., one formed by mixing fine conductive metal particles into a resin as a base) to perform communication by the circuits 903 formed on the semiconductor layer 1000a using radio waves transmitted/received by the antennas 901. Examples of the base resin include epoxy, urethane, acrylic resins, and the like, and among them all, epoxy is desirably used. As the conductive particles, gold, silver, nickel, carbon, or the like is desirably used. More specifically, an adhesive in which a microcapsule (MC) filler having silver (Ag) particles whose surfaces are coated with an insulating resin is uniformly dispersed is preferable. Advantageously, the adhesive costs little and is environmentally friendly. The thickness of the antenna 901 is not specifically limited, and is, for example, 15 μm.

Examples of the circuit 903 include a circuit which can be formed on the semiconductor layer 1000a such as an electronic circuit, oscillation circuit, optical waveguide, various sensors, and the like. The circuit 903 has a MOS transistor, bipolar transistor, diode, coil, capacitor, an element such as a light-receiving or light-emitting device, and the like. If the circuit 903 is applied to a device which performs radio communication, a radio circuit portion, ID authentication circuit, and the like are preferably formed on the circuit 903.

If, e.g., a semiconductor integrated circuit is to be formed on the semiconductor layer 1000a, the semiconductor layer 1000a is desirably one separated from a semiconductor substrate. As the semiconductor substrate, for example, a simple semiconductor of, e.g., silicon or a compound semiconductor of, e.g., gallium arsenide can be employed. The semiconductor layer is formed by separating a substrate including a separation layer at the separation layer. Thus, the semiconductor layer has a distinguishing feature that the thickness is extremely small. The thickness of the semiconductor layer 1000a is not specifically limited and is preferably 50 μm or less, more preferably, 30 μm or less, and most preferably, 20 μm.

The antenna substrate 1000b incorporates the antennas 901 and desirably comprises a dielectric substrate for use in, e.g., radio communication.

The device 1000 may be formed by bonding together the semiconductor layer 1000a and antenna substrate 1000b or bonding them together through the bonding layer 902, as shown in FIG. 9. The device 1000 according to the characteristic feature of this embodiment has the semiconductor layer with an extremely small thickness and consequently has a very small total thickness. The total thickness of the device 1000 is not specifically limited and is preferably, e.g., 100 μm or less, and more preferably, 50 μm or less (e.g., 25 μm). As a method of manufacturing the device 1000, a DLT (Device Layer Transfer) process is preferably used.

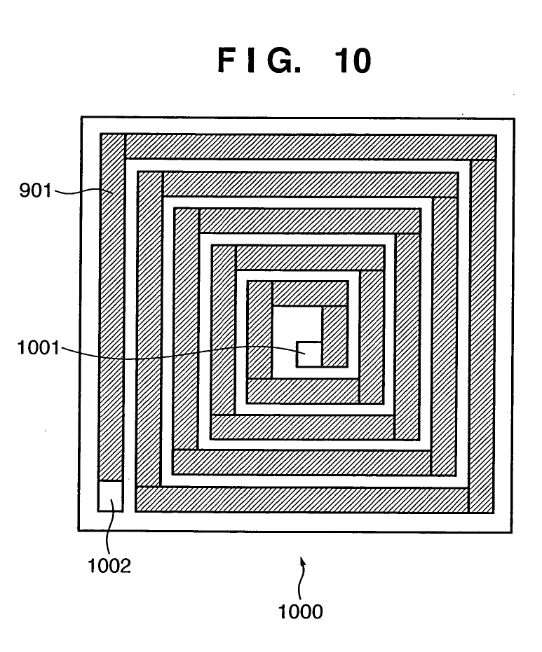

FIG. 10 is a plan view of the device 1000 in FIG. 9, as seen from above. When the antennas 901 are used as, e.g., ones for radio communication, they are desirably formed as spiral antenna coils, as shown in FIG. 10. The number of turns of the antenna coil is not specifically limited in this embodiment. The number of turns can be determined depending on operation of introducing an inductance into the circuit 903, operation of generating a magnetic flux, operation performed upon a change in magnetic flux, or the like. For example, if the circuit 903 is used as a high-frequency circuit, the antenna coil can be arranged to have a fraction of the above-mentioned number of turns. The antennas 901 are desirably connected to the semiconductor layer 1000a through pads 1001 and 1002. Each of the pads 1001 and 1002 desirably employs a conductive material to obtain good electrical contact between the antennas 901 and the semiconductor layer 1000a.

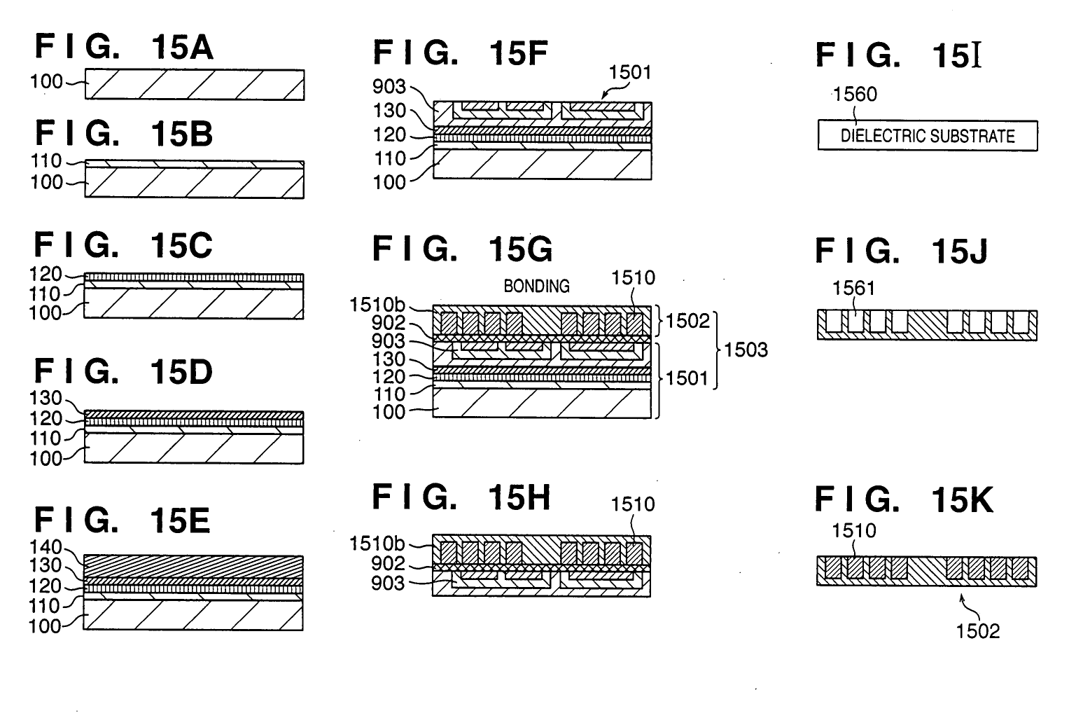

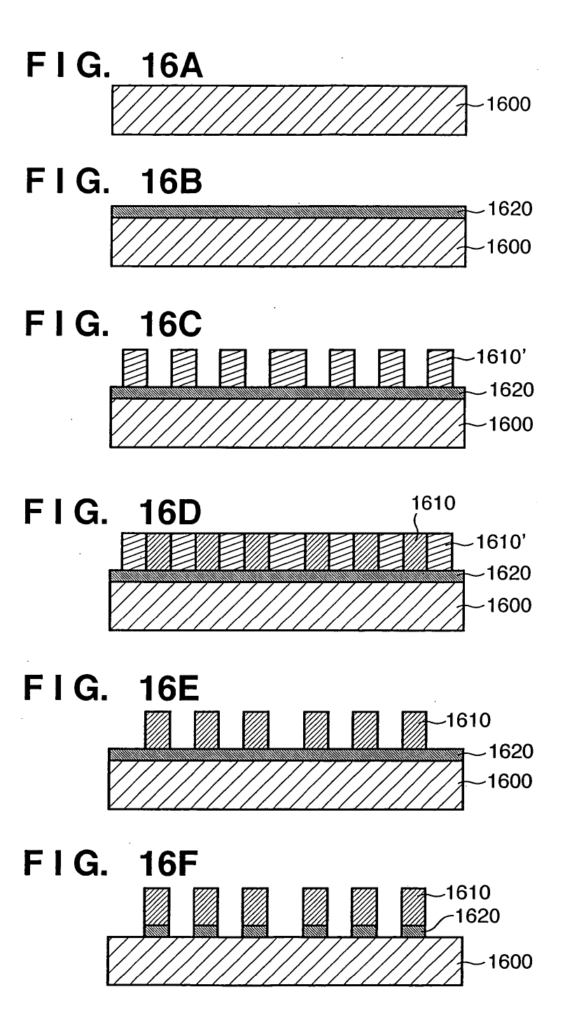

A method of manufacturing a bonded substrate stack according to the preferred embodiment of the present invention will be described below. FIGS. 15A to 15K are views for explaining a method of manufacturing the device 1000 according to the preferred embodiment of the present invention. FIGS. 15A to 15F show a process of forming the circuits 903 including, e.g., a radio circuit as the first substrate 1000a. FIGS. 15I to 15K show a process of forming-antennas 1510 on the second substrate 1000b. FIGS. 15G and 15H show a process of bonding together a first substrate 1501 in FIG. 15F and an antenna substrate 1502 in FIG. 15K. The method of manufacturing the device 1000 according to this embodiment is characterized by using a DLT (Device Layer Transfer) technique. The manufacturing method according to this embodiment is schematically obtained by changing some steps of the manufacturing process of FIG. 5 according to the first embodiment. More specifically, the steps of FIGS. 5F to 5H are replaced with the steps of FIGS. 15F to 15H and 15I to 15K or FIGS. 16A to 16F. In the step of FIG. 15F, the antenna substrate shown in FIGS. 15I to 15K or FIGS. 16A to 16F is used in place of the MEMS substrate in the step of FIG. 5F.

A method of manufacturing an antenna substrate according to this embodiment will be described first. FIGS. 15I to 15K are views showing a process of manufacturing an antenna substrate.

In the step shown in FIG. 15I, a dielectric substrate 1560 is prepared as an antenna substrate. The dielectric substrate 1560 is used to efficiently perform communication by antennas. For example, use of a metal substrate causes a large loss and makes it difficult to receive radio waves by the antennas.

In the step shown in FIG. 15J, a resist is applied to the dielectric substrate 1560. After a predetermined pattern is printed by exposure, etching is performed. Reference numeral 1561 denotes portions removed by etching.

In the step shown in FIG. 15K, the portions 1561 removed in the step shown in FIG. 15J are filled with a metal such as copper to form antenna patterns 1510. A method of filling a metal such as copper is, for example, plating.

Another method can be adopted as a process of forming an antenna substrate. FIGS. 16A to 16F show another process of forming an antenna substrate.

In the step shown in FIG. 16A, a dielectric substrate 1600 is prepared as an antenna substrate.

In the step shown in FIG. 16B, a metal layer 1620 is substantially uniformly formed on the dielectric substrate 1600 using copper, a copper alloy, aluminum, an aluminum alloy, or the like.

In the step shown in FIG. 16C, a photoresist layer 1610′ is substantially uniformly formed on the metal layer 1620 and is covered with a mask bearing a predetermined pattern including antenna coils. The photoresist layer 1610′ is irradiated with light having a predetermined wavelength from outside the mask and is subjected to exposure. The photoresist layer 1610′ having undergone the exposure is subjected to development to remove the exposed portion of the photoresist layer 1610′, thereby exposing a portion corresponding to the exposure pattern of the metal layer 1620.

In the step shown in FIG. 16D, the exposed portion of the metal layer 1620 is subjected to electroplating or precise electroforming to stack a photoresist layer 1610 on the exposed portion of the metal layer 1620.

In the step shown in FIG. 16E, the photoresist layer 1610′ is removed by ashing or the like, thereby forming the patterned metal plating layer (antenna coils) 1610 on the substantially uniform metal layer 1620.

In the step shown in FIG. 16F, the exposed portion of the metal layer 1620, which is a portion except a portion under the antenna coils 1610 as antennas is selectively etched and is removed. With this operation, the patterned antenna coils 1610 are formed on the dielectric substrate 1600.

Although electroplating or precise electroforming is employed to form the antenna coils 1610 in this embodiment, the present invention is not limited to this. For example, the antenna coils 1610 can be formed by electroless plating. In this case, no electrode is required to form the antenna coils 1610. This eliminates the need for forming an electrode portion connected to the metal layer 1620 and forming a lead portion.

Electroless plating is also called chemical plating for dipping a basis metal in a plating metallic salt solution to deposit metal ions on the surface of the basis metal. The characteristic feature of this method makes it possible to obtain a plating layer having firm adhesion and a uniform and sufficiently large thickness with relatively simple equipment. The metallic salt serves as a source of metal ions for plating. To apply a copper coating, a solution of copper sulfate, cupric chloride, copper nitrite, or the like is used as a plating solution. Ions of a metal such as copper are deposited only on the metal layer 1620 as the basis metal and are not deposited on the photoresist layer 1610′ as an insulating surface protective layer. The basis material needs to be unreactive to ions of a plating metal and catalyze the deposition of ions of the plating metal. For this reason, to plate the metal layer 1620 made of aluminum with copper, the following preprocess is preferably performed. More specifically, a nickel film is formed on the surface of the aluminum layer to a thickness of several μm or less, and the metal layer is dipped in a solution of zinc nitrite for several sec to substitute the nickel film with zinc.

Electroplating and precise electroforming is a method of dipping the dielectric substrate 1600 on which the metal layer 1620 is formed and an electrode made of a plating metal in a plating bath containing ions of the plating metal, applying a voltage using the metal layer 1620 formed on the dielectric substrate 1600 as a cathode and the electrode dipped in the plating bath as an anode, and depositing metal ions in the plating bath on the surface of the metal layer 1620. In electroplating and precise electroforming as well, a solution of copper sulfate, cupric chloride, copper nitrite, or the like is used as a plating solution to apply a copper coating.

An insulating film (not shown) as a protective film is desirably formed on each antenna coil 1610 and on its side in order to protect the antenna coil 1610. The insulating film can employ, e.g., a semi-cured epoxy resin having a thickness of 20 μm. For example, a semi-cured epoxy resin-based insulating adhesive film can be bonded. The insulating film may be made of another insulating resin such as polyimide, a metal oxide, or the like.

A method of manufacturing the device 1000 by bonding together the substrate 1501 obtained in the step of FIG. 15F and the antenna substrate 1502 obtained in the step of FIG. 15K will be described.

In the step shown in FIG. 15G, the substrate 1501 obtained in the step of FIG. 15F in the same manner as the substrate shown on the left side of FIG. 5F and the antenna substrate 1502 on which the antenna coils 1510 are formed are bonded together through the adhesion layer 902.

In the step shown in FIG. 15H, the resultant bonded substrate stack is separated at a separation layer comprised of a first porous Si layer 110 and second porous Si layer 120. More specifically, a pressure is applied by a fluid to the side of the separation layer comprised of the first porous Si layer 110 and second porous Si layer 120. To apply a pressure by a fluid, for example, a method of injecting the fluid made of a liquid or gas as a high-pressure jet to the side of the separation layer or a method of applying a hydrostatic pressure to the separation layer can be adopted. As the adhesion layer 902, an epoxy adhesive or any other adhesive can be used. As the fluid, a liquid such as water, an etchant, alcohol, or the like or a gas such as air, nitrogen gas, argon gas, or the like can be used. In the above-mentioned manner, the device 1000 as shown in FIG. 9 is obtained.

To separate the bonded substrate stack at the separation layer comprised of the first porous Si layer 110 and second porous Si layer 120, a method of applying ultrasonic vibrations can also be adopted. If the porous layer or ion-implanted layer as the separation layer is not exposed at the side surface of the member, the porous layer may be exposed by performing a process such as etching. The separated porous layer 120 may selectively be removed by, e.g., etching.

To separate the bonded substrate stack under a hydrostatic pressure (under a pressure applied by a substantially stationary fluid), for example, the following pressure application mechanism can be adopted. More specifically, an enclosed space component for enclosing at least part of the periphery of the member to form an enclosed space, and a pressure application mechanism capable of applying a pressure higher than the external space to the enclosed space can be adopted. Assume that the separation layer is formed by implanting ions of hydrogen, nitrogen, a rare gas such as He, or the like. Particularly in this case, when the bonded substrate stack is subjected to annealing at a temperature of about 400° C. to 600° C., micro air bubbles (microbubbles or microcavities) formed by ion implantation coagulate. The bonded substrate stack can be separated by utilizing a separation phenomenon which occurs upon applying a pressure by a fluid. The bonded substrate stack may be heated by, e.g., a CO₂ laser.

To form chips from the separation layer side, a general dicing apparatus can be used. In addition to this, e.g., etching, laser abrasion, a ultrasonic cutter, or a high-pressure jet (e.g., a water jet) can be used. To form chips by etching, an etchant such as a mixture of HF and H₂O₂, a mixture of HF and HNO₃, an alkali solution, or the like is preferably used. To form chips by a laser, a YAG laser, CO₂ laser, excimer laser, or the like can preferably be adopted.

Each semiconductor device and/or semiconductor integrated circuit 903 may be formed as a chip, and the device 1000 may be manufactured as a single or a plurality of radio tags. After chip formation, the device 1000 can be connected to another circuit or be packaged. The device 1000 can be transferred onto a plastic card.

The processing is desirably performed such that a trench or LOCOS (local oxidation of silicon) used for element isolation reaches the porous layer. Portions between regions in which chips are to be formed respectively may be subjected to LOCOS or mesa etching so as to remove a semiconductor film between the regions.

As described above, according to this embodiment, use of a semiconductor layer formed by separating a substrate including a separation layer at the separation layer can greatly thin the entire substrate. For this reason, a substrate (e.g., a radio tag) on which a circuit and antenna are formed can be thinned.

Accordingly, the difficulty of thinning a semiconductor layer can be solved, and a substrate on which a circuit and antenna are formed can effectively be manufactured.

Manufacturing a circuit and antenna in separate processes can solve the problem of an increase in process complexity and the problem of damage to an underlying circuit during the process.

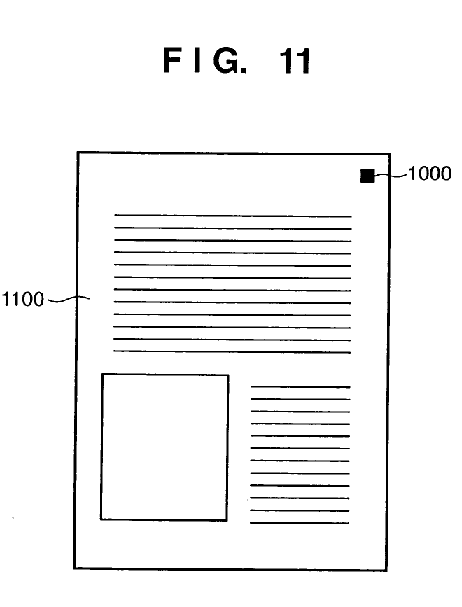

FIG. 11 is a view showing an application example which utilizes the features of the device 1000. FIG. 11 shows a structure in which the device 1000 according to this embodiment is bonded to a thin sheet 1100 of, e.g., paper. To bond the device 1000 to a thin material like the thin sheet 1100, the total thickness of the device 1000 needs to be thinned. The device 1000 according to this embodiment is characterized in that it can be manufactured to have a very small thickness. Thus, the device 1000 is suitable for being bonded to the thin sheet 1100 of, e.g., paper.

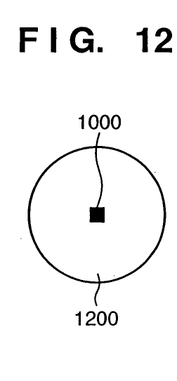

FIG. 12 is a view showing another application example which utilizes the features of the device 1000. FIG. 12 shows a structure in which the device 1000 according to this embodiment is adhered to, e.g., a seal 1200 having an adhesive portion on one side. The seal 1200 is advantageous in that the user can adhere it to a desired place. The device 1000 according to this embodiment can be manufactured to have a very small thickness and thus is suitable for being adhered to the seal 1200.

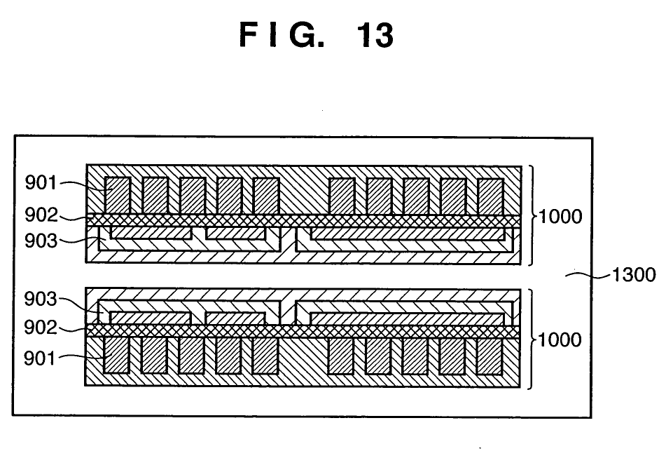

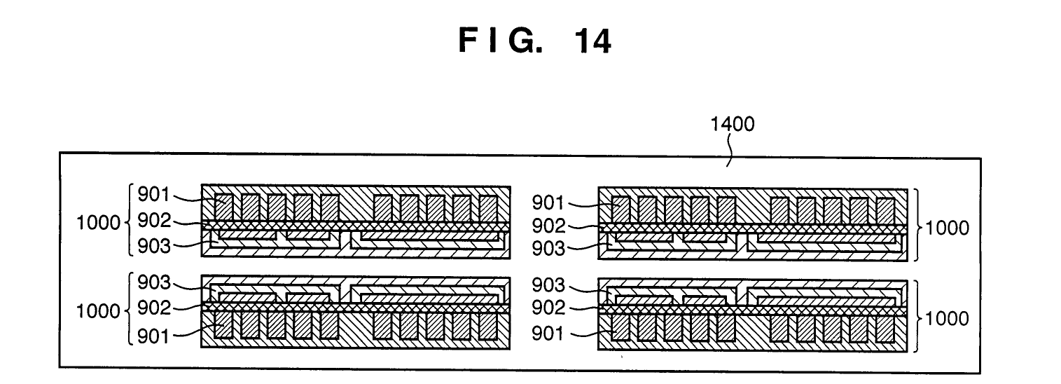

FIG. 13 is a sectional view showing a case wherein two devices 1000 according to this embodiment are stacked on a laminated plastic 1300. FIG. 14 is a sectional view showing a case wherein devices 1000 according to this embodiment are mounted on a laminated plastic 1400 in the same manner as in FIG. 13, and two more devices 1000 are laterally mounted. Referring to FIGS. 13 and 14, a plurality of devices 1000 are provided on each of the plastics 1300 and 1400. For this reason, if the devices 1000 are used for radio communication, causing the devices 1000 to incorporate different pieces of information or to support different frequencies enables the user to use the different frequencies.

Although in FIGS. 13 and 14, two layers of devices 1000 are stacked, the present invention is not limited to this. For example, a plurality of layers of devices 1000 may be stacked. However, if three or more layers are stacked, an antenna of the device 1000 near the center is sandwiched from both the sides by the opposing bonding substrate stacks. This makes it difficult for the antenna to perform communication. Thus, the devices 1000 are desirably stacked in about two layers.

By applying the steps of this embodiment to the process shown in FIGS. 5A to 5H, the MEMS switch 800 and antennas 802 shown in FIG. 7 can be packaged on a single substrate. This can be implemented by, e.g., further bonding the antenna substrate 1502 shown in FIG. 15K to the semiconductor circuit substrate shown in FIG. 5F in the step shown in FIG. 5G.

According to a bonded substrate stack as a radio tag and a manufacturing method thereof according to the preferred embodiment of the present invention, a bonded substrate stack (radio tag) which allows thinning can be formed. Also, an IC tag or IC card which is flexible and has high bending strength can be manufactured. As semiconductor devices are miniaturized and are highly integrated, the chip heat density increases significantly. When a bonded substrate stack according to the preferred embodiment of the present invention is applied to an LSI chip mounted on a thin device, the LSI chip can offer excellent heat dissipation.

As has been described above, the present invention can manufacture a thin substrate on which a circuit and an antenna are formed.

As many apparently widely different embodiments of the present invention can be made without departing from the spirit and scope thereof, it is to be understood that the invention is not limited to the specific embodiments thereof except as defined in the appended claims.

What is claimed is:

1. A device which has a semiconductor device and a micromachine, comprising:
a semiconductor layer on which the semiconductor device is formed; and
a substrate on which the micromachine is formed,
wherein said semiconductor layer and substrate are stacked, and said semiconductor layer is obtained by separating, at a separation layer, a member which has the separation layer under said semiconductor layer.

2. A device which has a semiconductor device and a micromachine, comprising:
a semiconductor layer on which the semiconductor device is formed; and
a substrate on which the micromachine is formed,
wherein said semiconductor layer has a first surface and a second surface, the first surface is bonded to said substrate directly or through a bonding layer, and the second surface adjoins a layer whose structure is more fragile than said semiconductor layer.

3. The device according to claim 2, wherein the layer having the fragile structure includes one of a porous layer and an ion-implanted layer.

4. A device which has a semiconductor device and a micromachine, comprising:
a semiconductor layer on which the semiconductor device is formed; and
a substrate on which the micromachine is formed,
wherein said semiconductor layer and substrate are stacked, and said semiconductor layer is formed by epitaxial growth.

5. The device according to claim 4, wherein said semiconductor layer has a first surface and a second surface, the first surface is bonded to said substrate directly or through a bonding layer, and the second surface is bonded to an insulator directly or through a bonding layer, or adjoins the insulator.

6. The device according to claim 2, wherein the bonding layer includes one of an adhesive and an adhesion layer.

7. A device which has a semiconductor device and a micromachine, comprising:
a semiconductor layer on which the semiconductor device is formed; and
a substrate on which the micromachine is formed,
wherein said semiconductor layer and substrate are stacked, and said semiconductor layer has a thickness of not more than 50 μm.

8. A device which has a semiconductor device and a micromachine, comprising:
a semiconductor layer on which the semiconductor device is formed; and
a substrate on which the micromachine is formed,
wherein said semiconductor layer and substrate are stacked, and said semiconductor layer has a thickness of not more than 30 μm.

9. The device according to claim 1, wherein the micromachine includes at least one of a switch, a variable condenser, and an inductor.

10. The device according to claim 1, wherein a semiconductor circuit is formed on said semiconductor layer, and the semiconductor circuit and micromachine comprise at least part of a radio communication device.

11. A substrate comprising:
a semiconductor layer on which a circuit is formed; and
an antenna substrate on which antennas are formed,
wherein said semiconductor layer and antenna substrate are bonded together, and said semiconductor layer is formed by separating, at a separation layer, a substrate which includes the separation layer.

12. The substrate according to claim 11, wherein said semiconductor layer has a film thickness of not more than 50 μm.

13. The substrate according to claim 11, wherein said semiconductor layer has a film thickness of not more than 30 μm.

14. The substrate according to claim 11, further comprising a bonding layer which bonds together said semiconductor layer and antenna substrate.

15. The substrate according to claim 14, wherein said bonding layer is an adhesive.

16. The substrate according to claim 11, wherein the antennas are spiral antenna coils.

17. The substrate according to claim 11, wherein the circuit is electrically connected to the antennas and uses the antennas to transmit and receive radio waves.

18. A method of manufacturing a device which has a semiconductor device and a micromachine, comprising:
a step of preparing a member which has a semiconductor layer and a separation layer and in which the semiconductor layer is arranged on the separation layer;
a step of preparing a substrate on which the micromachine is formed; and
a step of bonding a side of the member having the semiconductor layer to the substrate directly or through a bonding layer to manufacture a bonded substrate stack.

19. The method according to claim 18, further comprising a step of separating the bonded substrate stack at the separation layer.

20. The method according to claim 18, wherein in the step of preparing the member, the separation layer is formed by anodization or is formed by ion implantation.

21. The method according to claim 18, wherein the bonding layer includes one of an adhesive and an adhesion layer.

22. The method according to claim 18, wherein
the step of preparing the substrate further comprises a step of preparing an antenna substrate on which an antenna is formed, and
the step of manufacturing the bonded substrate stack further comprises a step of bonding the side of the member having the semiconductor layer to the antenna substrate directly or through a bonding layer to manufacture a bonded substrate stack.

23. A method of manufacturing a substrate, comprising:
a step of preparing a member which has a semiconductor layer and a separation layer and in which the semiconductor layer is arranged on the separation layer;
a step of preparing an antenna substrate on which an antenna is formed; and
a step of bonding a side of the member having the semiconductor layer to the antenna substrate directly or through a bonding layer to manufacture a bonded substrate stack.

24. The method according to claim 23, further comprising a step of separating the bonded substrate stack at the separation layer.
